(19) United States
(12) Patent Application Publication
(10) Pub. No.: US 2007/0018073 A1
(43) Pub. Date: Jan. 25, 2007

(54) CMOS image sensor device with beehive pattern color sensor cell array

(75) Inventors: Tzu-Hsuan Hsu, Kaohsiung City (TW); Dun-Nian Yaung, Taipei City (TW); Chih-Kung Chang, Cha-Tung (TW)

Correspondence Address: Howard Chen;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/213,186

(22) Filed: Aug. 25, 2005

Related U.S. Application Data
(60) Provisional application No. 60/701,713, filed on Jul. 22, 2005.

(51) Int. Cl. H01L 27/00

(52) U.S. Cl. 250/208.1

(57) ABSTRACT

A CMOS image sensor cell includes a first pixel area in which at least one first photodiode is disposed for generating a first sense signal in response to a photo-signal of a first color; a second pixel area neighboring the first pixel area, in which at least one second photodiode is disposed for generating a second sense signal in response to a photo-signal of a second color; and a third pixel area neighboring the first and second pixel areas, in which at least one third photodiode is disposed for generating a third sense signal in response to a photo-signal of a third color. A sense amplifier is disposed substantially within the first, second and third pixel areas for amplifying the first, second and third sense signals. The first, second and third pixel areas that substantially occupy an entire area of the image sensor cell are substantially equal in size.

### CROSS REFERENCE TO RELATED APPLICATION

This application is related to, and claims the benefits of U.S. Provisional Patent Application Ser. No. 60/701,713, entitled CMOS IMAGE SENSOR DEVICE WITH BEEHIVE PATTERN COLOR SENSOR CELL ARRAY, which was filed on Jul. 22, 2005.

### BACKGROUND

The present invention relates generally to an integrated circuit (IC) design, and more particularly to a complementary metal-oxide-semiconductor (CMOS) image sensor device.

A color CMOS image sensor is commonly used for providing a real color image, and can be easily found in electronic devices such as a digital camera. A color CMOS image sensor produces a digital/analog output representing each pixel of an image, and is designed to draw much less power than a conventional charge-coupled device (CCD), thereby increasing battery life for many of today's consumer electronics. The color CMOS image sensor typically includes at least one micro-lens, color filters, at least one photodiode, a transfer transistor coupled with the photodiode, and a sense amplifier for amplifying a sense signal generated by the photodiode. A combination of various color photodiodes works together with the color filters to provide the image sensor with a real color image.

While many layout patterns are available for image sensor cell arrays, one of the most widely used layout patterns for conventional image sensor cell arrays is the Bayer pattern. A Bayer pattern image sensor cell is composed of four square-shaped pixels placed together in a 2×2 formation. Due to its shape and formation, two green pixels are placed in opposite corners along with one red pixel and one blue pixel in the other corners to represent one real color.

However, the conventional Bayer pattern image sensor cell is not the perfect layout in chromatography, and suffers from many issues such as a poor fill factor, color distortion, cross-talk noise, poor quantum efficiency, and micro-lens corner rounding.

Thus, it is desirable to have an image sensor cell that can address the above issues.

### SUMMARY

This invention discloses an image sensor cell for a CMOS image sensor device. In one embodiment of the present invention, the image sensor cell includes a first pixel area in which at least one first photodiode is disposed for generating a first sense signal in response to a photo-signal of a first color; a second pixel area neighboring the first pixel area, in which at least one second photodiode is disposed for generating a second sense signal in response to a photo-signal of a second color; and a third pixel area neighboring the first and second pixel areas, in which at least one third photodiode is disposed for generating a third sense signal in response to a photo-signal of a third color. At least one sense amplifier is disposed substantially within the first, second and third pixel areas for amplifying the first, second and third sense signals. The first, second and third pixel areas that substantially occupy an entire area of the image sensor cell are substantially equal in size.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1A illustrates a conventional Bayer pattern image sensor cell array.

FIG. 1B illustrates a diagram showing the micro-lens corner rounding effect caused by the conventional Bayer pattern image sensor cell array.

FIG. 2A illustrates a beehive image sensor cell array in accordance with one embodiment of the present invention.

FIG. 2B schematically illustrates a circuit diagram of an image sensor cell in accordance with one embodiment of the present invention.

FIG. 3A illustrates a graph showing a comparison of the fill factors between the Bayer pattern image sensor cell and the proposed beehive image sensor cell.

FIG. 3B illustrates a graph showing a comparison of the quantum efficiencies between the Bayer pattern image sensor cell and the proposed beehive image sensor cell.

FIG. 3C illustrates a graph showing a comparison of the micro-lens effective area ratios between the Bayer pattern image sensor cell and the proposed beehive layout sensor cell.

### DESCRIPTION

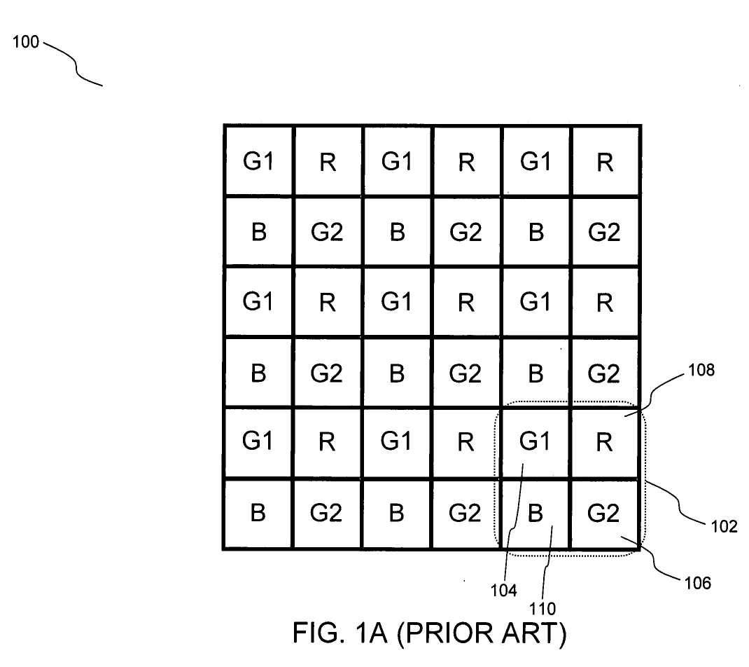

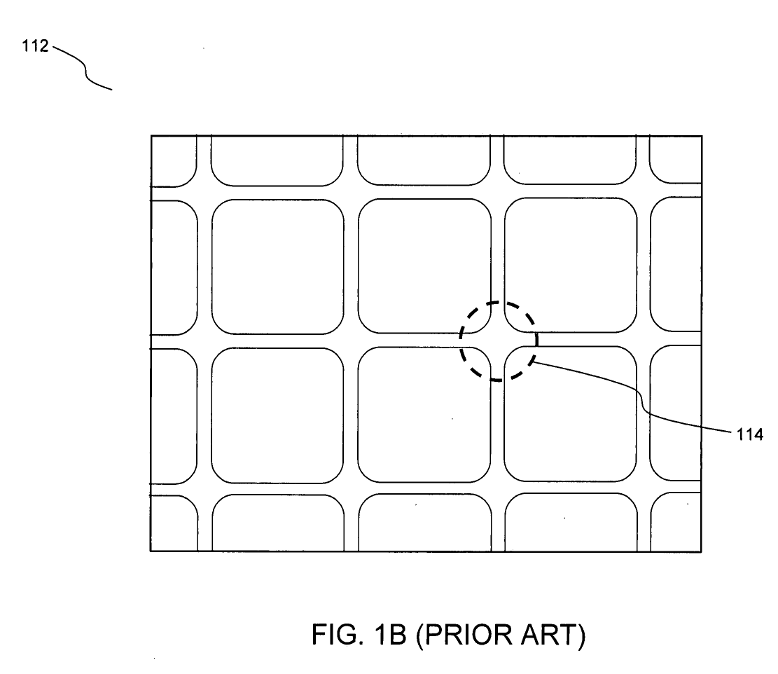

FIG. 1A illustrates a diagram 100 showing a conventional Bayer pattern image sensor cell array. The Bayer pattern image sensor cells are placed in a 3×3 formation, with three rows and three columns of cells. Each Bayer pattern image sensor cell, such as an image sensor cell 102, requires a total of four square pixel areas placed together to present a real color. In each Bayer pattern image sensor cell, one blue pixel area, one red pixel area, and two green pixel areas are used. One or more electrical devices, such as photodiodes and transistors, are disposed within the pixel areas for generating sense signals in response to photo-signals of various colors. In the Bayer pattern image sensor cell 102, a green pixel area 104 is placed in the upper-left corner while another green pixel area 106 is placed in the lower-right corner. The red pixel area 108 is placed in the upper-right corner and the blue pixel area 110 is placed in the lower-left corner. With this formation, the Bayer pattern image sensor cells within the diagram 100 can provide real color sensing capability for a broad image.

This conventional type of image sensor cell has certain drawbacks such as color distortion and cross-talk noise. As shown in the Bayer pattern image sensor cell 102, a real color created from this formation is represented by using four color pixels areas including two green color pixel areas 104 and 106 and only one red pixel area 108 and one blue pixel area 110. This creates an unbalanced color distribution leading toward color distortion and differential-mode cross-talk noise.

The square-shaped Bayer pattern image sensor cell requires square-shaped micro-lenses. FIG. 1B illustrates a diagram 112 showing a set of micro-lenses which are constructed on a micro-lens layer of the image sensor cell array. While each pixel area illustrated in FIG. 1A has a perfect 90-degree corner, in reality, the square micro-lens used for the pixel area is rounded-off at its corners. An area 114 is circled to show an area loss among four neighboring micro-lenses. The loss in the micro-lens area degrades the photo-sensitivity of the conventional image senor cell.

A pixel area may have a photodiode for sensing photo-signals and some electrical devices for controlling and amplifying a sense signal generated by the photodiode. The fill factor, defined as the photodiode area divided by the pixel area, is a parameter used to measure the effectiveness of an image sensor cell. As the size of the image sensor cell continues to shrink in newer technologies, the size of the electrical device within a pixel area can hardly be reduced, and only the size of the photodiode can be reduced in a greater scale. For each conventional Bayer pattern image sensor cell, each pixel area is relatively small due to the relatively large number of pixel areas. Since the size of the electrical devices can hardly be reduced, a small pixel area means an even smaller photodiode area and fill factor, which is proportionate to the photo-sensitivity. Thus, the conventional image sensor cell is very susceptible to the further shrinkage in size.

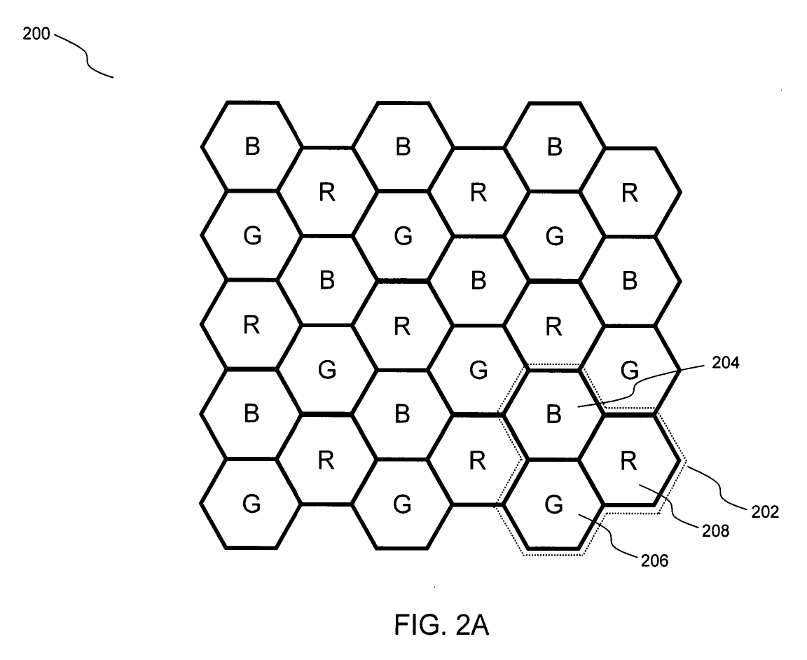

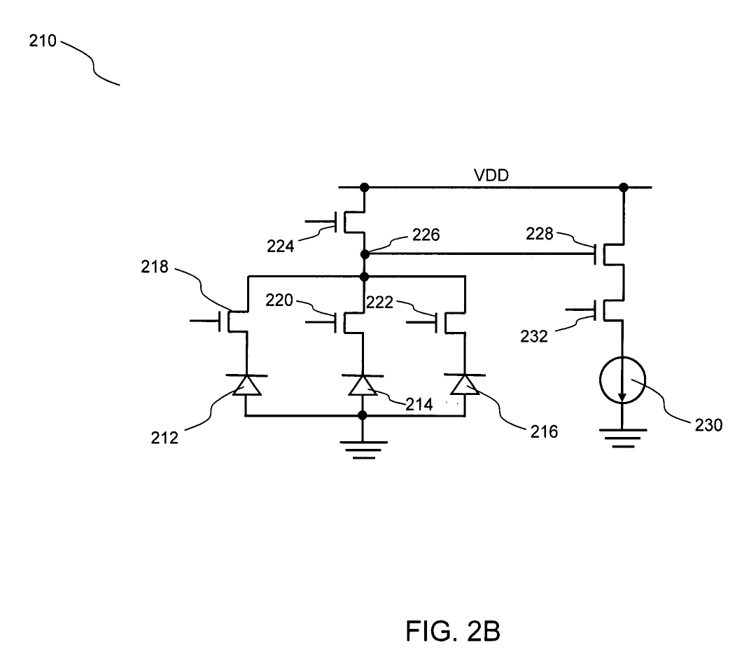

FIG. 2A illustrates a diagram showing a beehive image sensor cell array 200 in accordance with one embodiment of the present invention. The diagram of FIG. 2A shows nine image sensor cells arranged in a 3×3 formation. Each image sensor cell, such as the cell 202, includes a total of three hexagon-shaped pixel areas placed together for representing a real color. For example, in the image sensor cell 202, a blue pixel area 204 is placed in the upper-left position while a green pixel area 206 is placed in the lower-left position. A red pixel area 208 is placed at the right side of the cell, neighboring both the blue pixel area 204 and the green pixel area 206. The blue and green pixel areas 204 and 206 share one common boundary line, while the green and red pixel areas 206 and 208 share another common boundary line. The red and blue pixel areas 208 and 204 share yet another common boundary line. The red, green and blue pixel areas 208, 206 and 204 are substantially equal in size, and substantially occupy an entire area of the image sensor cell 202. The array 200 includes a plurality of image sensor cells according to a specific layout and arrangement. For example, pixels neighboring the first pixel are the second and third pixels, pixels neighboring the second pixel are the first and third pixels, and pixels neighboring the third pixel are the first and second pixels.

It is noted that in another embodiment, the pixel areas 204, 206 and 208 can be of a circular shape in contact with each other. It is understood by people skilled in the art of the CMOS image sensor technology that a pixel area incorporates a multiple layer semiconductor structure, on which layers of micro-lens, color filters, photodiodes and control devices may be constructed.

FIG. 2B schematically illustrates a circuit diagram 210 showing an image sensor cell implemented within its pixel areas in accordance with one embodiment of the present invention. The circuit diagram 210 includes three photodiodes 212, 214, and 216, each generating a sense signal in response to a photo-signal of a predetermined color. For example, the photodiode 212 provides a first sense signal in response to a red color light, while the photodiodes 214 and 216 provide second and third sense signals in response to a green color light and a blue color light, respectively. The cathode of each photodiode is coupled to a source of its corresponding MOS transfer transistor, such as a transistor 218, 220 or 222, which is implemented in its corresponding pixel area. Each of the transfer transistors 218, 220 and 222 is controlled by a select signal that is applied to the gate of the transistor. The transfer transistor passes the sense signal generated by its corresponding photodiode when it is turned on by the select signal.

A sense amplifier, which is collectively represented by a reset transistor 224, a source follower transistor 228, a row select transistor 232 and a source current 230, is implemented within the red, green and blue pixel areas for amplifying the outputs from the transfer transistors 218, 220 and 222. The reset transistor 224 has its drain coupled to the operation voltage VDD and its source coupled to the outputs of the transfer transistors 218, 220, and 222 via a node 226. A source-follower transistor 228, with its gate coupled to the node 226, drain coupled to the operation voltage VDD and source coupled to a source current 230 via a row select transistor 232, is implemented to provide the circuit with a source current 230. When the source-follower transistor 228 is turned on from the voltage at the node 226, the source current 230 can reach the supply voltage VDD when a row select transistor 232 is turned on. The source current 230 may be used as a reference current for this amplifier circuit.

The proposed beehive image sensor cell array provides many advantages over the conventional Bayer pattern image sensor cell array. For example, by placing only one red pixel area, one green pixel area, and one blue pixel area in a beehive-shaped formation, a better image with more balanced color distribution can be achieved. Also, the area loss due to the micro-lens corner rounding effect is avoided. Since each color pixel area is symmetrically surrounded by other color pixel areas, the cross-talk will be in a form of common mode noise, which will provide better color purity over the differential-mode cross-talk noise caused by the conventional Bayer pattern image sensor cell.

The fill factor of the beehive pattern image sensor cell is also much better than that of the conventional Bayer pattern image sensor cell. As the size of the image sensor cell continues to shrink in new technologies, the fill factor decreases even faster than the rate of the image sensor cell shrinkage. For a proposed image sensor cell and a same-sized conventional image sensor cell, each pixel area of the proposed cell is larger than that of the conventional cell, since the proposed cell only includes three color pixels while the conventional cell includes four. Thus, the fill factor of the proposed cell is less susceptible to the cell size shrinkage than that of the conventional cell. The proposed beehive-shaped pattern for image sensor cells is particularly advantageous for image sensing device of a small size, such as a CMOS image sensor device. This advantage may not be readily appreciated for a CCD device, which typically has a relatively large area for construction of the image sensor cells.

The advantage of this less sensitive fill factor compels the proposed image sensor array to be used for a CMOS image sensor device, instead of a CCD device. Each pixel area of a CCD sensor cell typically includes only one photodiode and one transistor, while each pixel area of a CMOS image sensor cell typically includes one photodiode and multiple transistors. In other words, a CMOS image sensor device is much more susceptible to the fill factor issue, as its size continues to shrink. Since the fill factor is not much of a problem for CCD devices, the proposed image cell array can provide a lot more advantages by being used in CMOS image sensor devices.

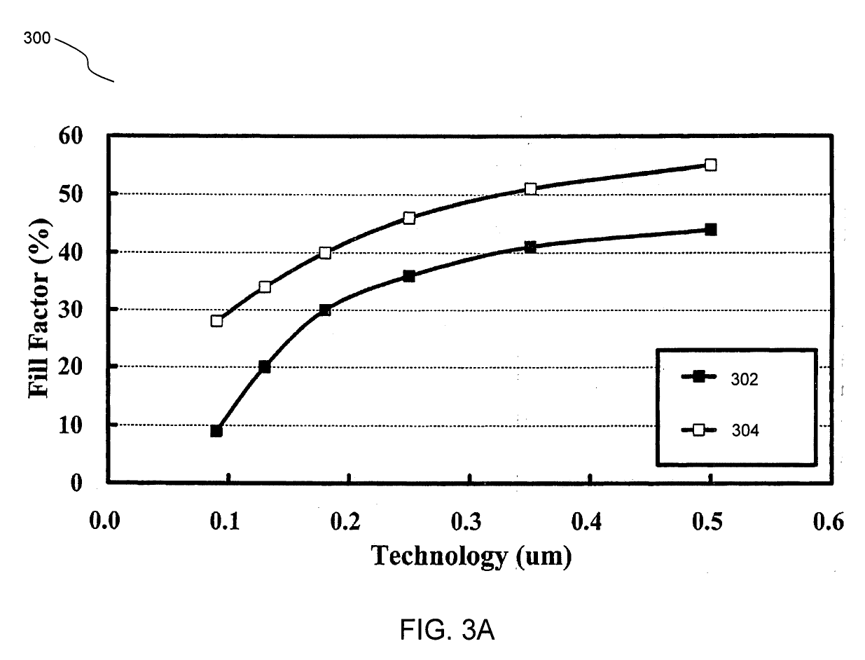

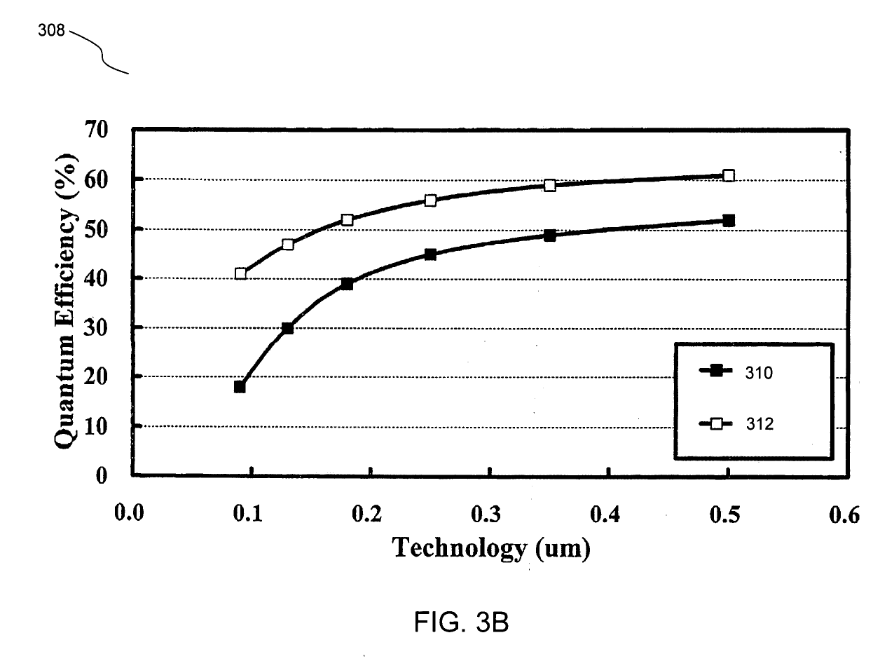

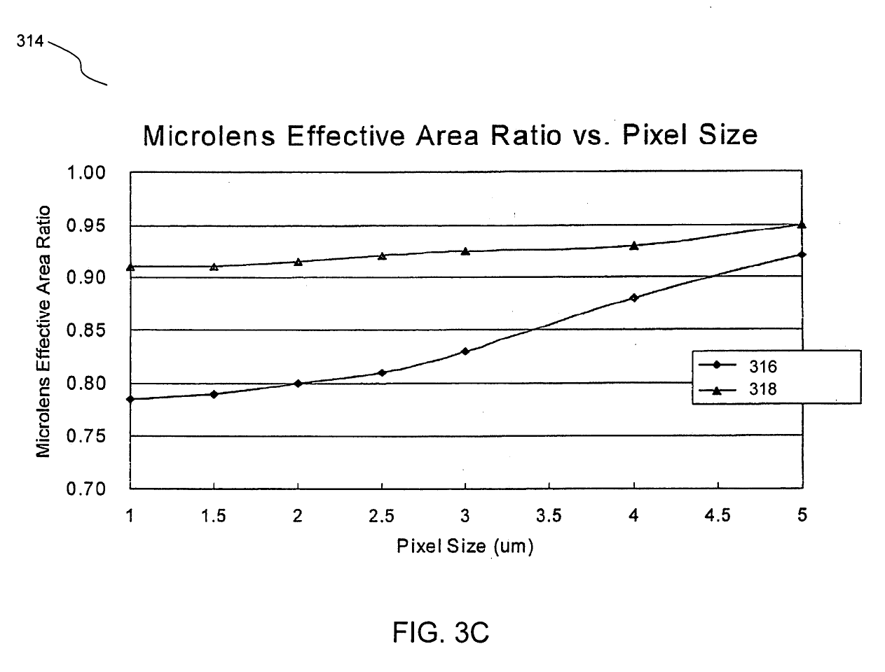

FIG. 3A illustrates a graph 300 showing a comparison of the fill factors between the conventional Bayer pattern image sensor cell of FIG. 1A and the beehive image sensor cell of FIG. 2A. A curve 302 represents the fill factor percentage of the conventional Bayer pattern image sensor cell, while a curve 304 represents the fill factor percentage of the beehive image sensor cell. The curves 302 and 304 show the fill factors of both the conventional cell and the proposed cell fabricated using a CMOS technology scale from 0.1 μm to 0.5 μm. As the graph shows, the fill factor for both curves 302 and 304 decreases as the technology scale shrinks. However, it is obvious that the proposed cell provides a much higher fill factor in comparison with the conventional cell in the same technology scale.

FIG. 3B illustrates a graph 308 showing a comparison of the quantum efficiencies, defined as the output signal (electron) divided by the input signal (photon), between the conventional Bayer pattern image sensor cell of FIG. 1A and the beehive image sensor cell of FIG. 2A. A curve 310 represents the quantum efficiency percentage of the conventional cell, while a curve 312 represents the quantum efficiency percentage of the proposed cell. The curves 310 and 312 show the quantum efficiency of both the conventional cell and the proposed cell fabricated using a technology scale from 0.1 μm to 0.5 μm. As the graph shows, the quantum efficiency for both curves 310 and 312 decreases as the technology shrinks. However, it is obvious that the proposed cell provides much higher quantum efficiency in comparison with the conventional cell in the same technology scale.

FIG. 3C illustrates a graph 314 showing a comparison of the micro-lens effective area ratios between the conventional Bayer pattern image sensor cell of FIG. 1A and the beehive image sensor cell of FIG. 2A. The micro-lens effective area can be defined as the ratio of the actual area in pixels to the layout area of the pixels. A curve 316 represents the micro-lens effective area ratio of the conventional cell, while a curve 318 represents the micro-lens effective area ratio of the proposed cell. The curves 316 and 318 show the micro-lens effective area ratio of both the conventional cell and the proposed cell fabricated using a technology scale from 0.1 μm to 0.5 μm. As the graph shows, the micro-lens effective area ratio for both curves 316 and 318 decreases as the technology scale shrinks. However, it is obvious that the proposed cell provides a much higher actual pixel area to pixel layout area ratio in comparison with the conventional cell in the same technology scale.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. An image sensor cell for a complementary metal-oxide-semiconductor (CMOS) image sensor device, comprising:
a first pixel area in which at least one first photodiode is disposed for generating a first sense signal in response to a photo-signal of a first color;
a second pixel area neighboring the first pixel area, in which at least one second photodiode is disposed for generating a second sense signal in response to a photo-signal of a second color;
a third pixel area neighboring the first and second pixel areas, in which at least one third photodiode is disposed for generating a third sense signal in response to a photo-signal of a third color; and
at least one sense amplifier disposed substantially within the first, second and third pixel areas for amplifying the first, second and third sense signals,
wherein the first, second and third pixel areas that substantially occupy an entire area of the image sensor cell.

2. The image sensor cell of claim 1 wherein the first, second and third pixel areas are of a substantially hexagonal shape.

3. The image sensor cell of claim 2 wherein the first and second pixel areas share one common boundary line, the second and third pixel areas share another common boundary line, and the third and first pixel areas share yet another common boundary line.

4. The image sensor cell of claim 1 wherein the first color is red, the second color is green and the third color is blue.

5. The image sensor cell of claim 1 further comprising a first transistor disposed within the first pixel area and coupled to the first photodiode for selectively passing the first sense signal thereacross.

6. The image sensor cell of claim 5 further comprising a second transistor disposed within the second pixel area and coupled to the second photodiode for selectively passing the second sense signal thereacross.

7. The image sensor cell of claim 6 further comprising a third transistor disposed within the third pixel area and coupled to the third photodiode for selectively passing the third sense signal thereacross.

8. The image sensor cell of claim 7 wherein the sense amplifier further comprises a source follower transistor having a drain coupled to an operation voltage and a gate coupled to outputs of the first, second and third transistors for passing the operation voltage to its source in response to the outputs thereof.

9. The image sensor cell of claim 8 wherein the sense amplifier further comprises a reset transistor having a drain coupled to the operation voltage and a source coupled to the gate of the source follower transistor and the outputs of the first, second and third transistors for selectively passing the operation voltage to the gate of the source follower transistor.

10. The image sensor cell of claim 9 wherein the sense amplifier further comprises a select transistor coupled between the source of the source follower transistor and a source current.

11. The image sensor cell of claim 1 wherein the first, second and third pixel areas are of a substantially circular shape in contact with each other.

12. A complementary metal-oxide-semiconductor (CMOS) image sensor device having an array of image sensor cells sensitive to photo-signals, each image sensor cell comprising:
a first hexagonal pixel area in which at least one first photodiode is disposed for generating a first sense signal in response to a photo-signal of a first color;
a second hexagonal pixel area neighboring the first hexagonal pixel area, in which at least one second photodiode is disposed for generating a second sense signal in response to a photo-signal of a second color;
a third hexagonal pixel area neighboring the first and second hexagonal pixel areas, in which at least one third photodiode is disposed for generating a third sense signal in response to a photo-signal of a third color; and
at least one sense amplifier disposed substantially within the first, second and third hexagonal pixel areas for amplifying the first, second and third sense signals,
wherein the first, second and third hexagonal pixel areas that substantially occupy an entire area of the image sensor cell.

13. The CMOS image sensor device of claim 12 wherein the first and second hexagonal pixel areas share one common boundary line, the second and third hexagonal pixel areas share another common boundary line, and the third and first hexagonal pixel areas share yet another common boundary line.

14. The CMOS image sensor device of claim 12 wherein the first color is red, the second color is green and the third color is blue.

15. The CMOS image sensor device of claim 12 further comprising a first transistor disposed within the first hexagonal pixel area and coupled to the first photodiode for selectively passing the first sense signal thereacross, a second transistor disposed within the second hexagonal pixel area and coupled to the second photodiode for selectively passing the second sense signal thereacross, and a third transistor disposed within the third hexagonal pixel area and coupled to the third photodiode for selectively passing the third sense signal thereacross.

16. The CMOS image sensor of claim 15 wherein the sense amplifier further comprises a source follower transistor having a drain coupled to an operation voltage and a gate coupled to outputs of the first, second and third transistors for passing the operation voltage to its source in response to the outputs thereof.

17. The CMOS image sensor of claim 15 wherein the source follower transistor, first, second and third transistors are MOSFETs.

18. A complementary metal-oxide-semiconductor (CMOS) image sensor array sensitive to photo-signals, comprising:
a plurality of image sensor cells, each image sensor cell including a first pixel, a second pixel and a third pixel, pixels neighboring the first pixel being the second and third pixels, pixels neighboring the second pixel being the first and third pixels, and pixels neighboring the third pixel being the first and second pixel.

19. The CMOS image sensor array of claim 18 wherein the first pixel represents red color, the second pixel represents green color, and the third pixel represents blue color.
